(19) United States
(12) Patent Application Publication
(10) Pub. No.: US 2025/0374401 A1
(43) Pub. Date: Dec. 4, 2025

(54) LIGHT SOURCE

(71) Applicant: Nichia Corporation, Anan-shi (JP)

(72) Inventors: Masato OGAWA, Anan-shi (JP); Yusaku ACHI, Tokushima-shi (JP); Kohei SUZAKI, Komatsushima-shi (JP)

(21) Appl. No.: 19/208,090

(22) Filed: May 14, 2025

(30) Foreign Application Priority Data
May 28, 2024 (JP) 2024-086429

(51) Int. Cl. H05B 45/40; H10H 29/24

(52) U.S. Cl. CPC H05B 45/40; H10H 29/24

(57) ABSTRACT

A light source includes a first light-emitting unit including one or more first light-emitting elements connected in series, a second light-emitting unit including second light-emitting elements connected in series. The number of the second light-emitting elements is greater than that of the one or more first light-emitting elements. The first and second light-emitting units are connected in parallel to each other. A first light emission peak wavelength of the first light-emitting element is different from a second light emission peak wavelength of the second light-emitting element. A second forward voltage of the second light-emitting element is lower than a first forward voltage of the first light-emitting element. An absolute value of a difference between a forward voltage of the first light-emitting unit and a forward voltage of the second light-emitting unit is lower than the second forward voltage of the second light-emitting element.

### CROSS-REFERENCE TO RELATED APPLICATION

This application claims priority to Japanese Patent Application No. 2024-086429 filed on May 28, 2024, the disclosure of which is hereby incorporated by reference in its entirety.

### BACKGROUND

### Technical Field

The present disclosure relates to a light source.

### Background Art

Japanese Patent Application Publication No. 2013-026510 A discloses an LED module including a plurality of LED chips that emit light beams of different colors.

### SUMMARY

An object of the present disclosure is to provide a light source that can reduce power consumption.

According to an aspect of the present disclosure, a light source includes: a substrate; a first light-emitting unit disposed on the substrate and including one first light-emitting element or a plurality of first light-emitting elements connected in series; a second light-emitting unit disposed on the substrate and including a plurality of second light-emitting elements connected in series, the number of the plurality of second light-emitting elements being greater than the number of the one or plurality of first light-emitting elements; a power supply configured to supply electric power to the one or plurality of first light-emitting elements and the second light-emitting elements; and one or more drivers configured to cause the one or plurality of first light-emitting elements and the plurality of second light-emitting elements to emit light of predetermined brightnesses, in which the first light-emitting unit and the second light-emitting unit are connected in parallel to each other with respect to the power supply, a first light emission peak wavelength of each of the one or plurality of first light-emitting elements is different from a second light emission peak wavelength of each of the plurality of second light-emitting elements, a second forward voltage of each of the plurality of second light-emitting elements is lower than a first forward voltage of each of the one or plurality of first light-emitting elements, and an absolute value of a difference between a first voltage, which is a forward voltage of the first light-emitting unit, and a second voltage, which is a forward voltage of the second light-emitting unit, is lower than the second forward voltage of each of the second light-emitting elements.

According to certain embodiments of the present disclosure, a light source with reduced power consumption can be provided.

### BRIEF DESCRIPTION OF DRAWINGS

FIG. 1 is an equivalent circuit diagram illustrating a configuration of a light source according to an embodiment.

FIG. 2 is a graph showing a relationship between a second duty cycle and a second forward voltage for a second light-emitting element of the light source according to an embodiment.

FIG. 3 is a graph showing a relationship between a second pulse forward current and a second forward voltage for the second light-emitting element of the light source according to the embodiment.

FIG. 4 schematically illustrates a cross-sectional view of the light source according to the embodiment.

FIG. 5 schematically illustrates a perspective view of a light-emitting device in the light source according to an embodiment.

FIG. 6 schematically illustrates a perspective view of the light-emitting device in the light source according to the embodiment.

FIG. 7 schematically illustrates a schematic diagram illustrating the light-emitting device in the light source according to the embodiment when viewed from different directions.

FIG. 8 schematically illustrates a cross-sectional view of the light-emitting device taken along line VIII-VIII in FIG. 7.

FIG. 9 schematically illustrates a cross-sectional view of the light-emitting device taken along line IX-IX in FIG. 7.

FIG. 10 schematically illustrates a cross-sectional view of the light-emitting device taken along line X-X in FIG. 7.

FIG. 11 schematically illustrates a front view of a light-emitting device according to a modification of the embodiment.

FIG. 12 schematically illustrates a perspective view of the light-emitting device according to the modification of the embodiment.

### DETAILED DESCRIPTION

Light sources according to certain embodiments of the present disclosure will be described below with reference to the drawings. Dimensions, materials, shapes, relative arrangements, or the like of constituent members described in the embodiments are not intended to limit the scope of the present disclosure thereto, unless otherwise specified, and are merely exemplary. It is noted that the sizes, positional relationship, or the like of members illustrated in each of the drawings may be exaggerated for clarity of description. Furthermore, in the following description, members having the same names and reference signs represent the same members or members of the same quality, and detailed description of these members is omitted as appropriate. As a cross-sectional view, an end view illustrating only a cut surface may be illustrated.

In the following description, terms indicating specific directions or positions (for example, “upper”, “lower”, and other terms including those terms) may be used. However, these terms are used merely to make it easy to understand relative directions or positions in the referenced drawing. As long as the relative direction or position is the same as that described in the referenced drawing using the term such as “upper” or “lower,” in drawings other than the drawings of the present disclosure, actual products, and the like, components need not be arranged in the same manner as that in the referenced drawing.

In the following drawings, directions may be indicated by an X axis, a Y axis, and a Z axis, which are perpendicular to each other. For example, in the present specification, a direction along the X-axis is referred to as a first direction X, a direction along the Y-axis is referred to as a second direction Y, and a direction along the Z-axis is referred to as a third direction Z. In addition, in a relative sense, the positive direction of the X axis is referred to as +X side, and the negative direction of the X axis is referred to as −X side. The positive direction of the Y-axis is referred to as upward, and the negative direction is referred to as downward, in a relative sense.

### Light Source

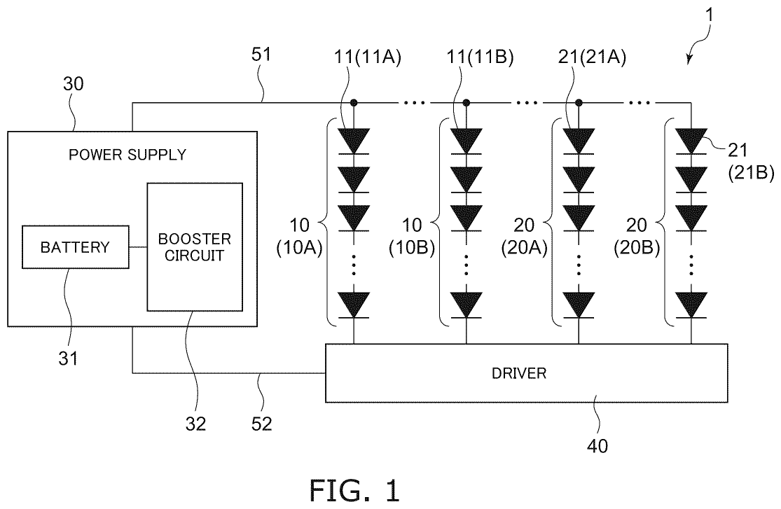

FIG. 1 is an equivalent circuit diagram illustrating a configuration of a light source 1 according to an embodiment.

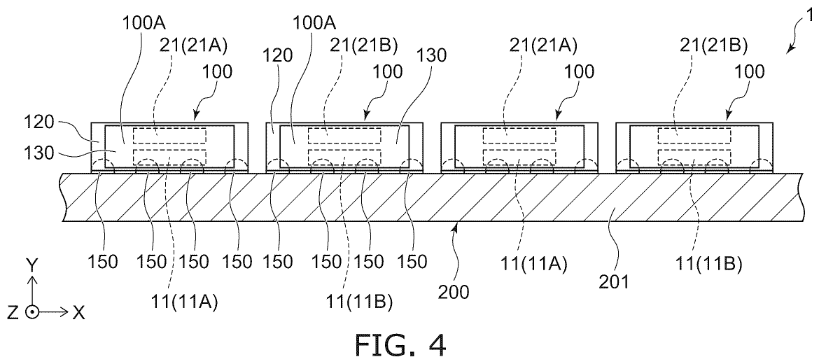

The light source 1 according to the embodiment includes a first light-emitting unit 10, a second light-emitting unit 20, a power supply 30, and a driver 40. The light source 1 further includes a substrate 200 illustrated in FIG. 4 described below.

The first light-emitting unit 10 includes one first light-emitting element or a plurality of first light-emitting elements 11 connected in series. The second light-emitting unit 20 includes a plurality of second light-emitting elements 21 connected in series, and the number of the second light-emitting elements 21 is greater than the number of the first light-emitting element(s) 11. The first light-emitting unit 10 and the second light-emitting unit 20 are connected in parallel to each other with respect to the power supply 30. In the example illustrated in FIG. 1, a plurality of first light-emitting units 10 and a plurality of second light-emitting units 20 are connected in parallel to each other with respect to the power supply 30. A single first light-emitting unit 10 and a plurality of second light-emitting units 20 may be connected in parallel to each other with respect to the power supply 30. A plurality of first light-emitting units 10 and a single second light-emitting unit 20 may be connected in parallel to each other with respect to the power supply 30. A single first light-emitting unit 10 and a single second light-emitting unit 20 may be connected in parallel to each other with respect to the power supply 30. In the light source 1, the first light-emitting unit(s) 10 and the second light-emitting unit(s) 20 are connected in parallel to each other, and the light source 1 need not include the power supply 30.

The power supply 30 supplies electric power to the first light-emitting element(s) 11 of the first light-emitting unit 10 and the second light-emitting elements 21 of the second light-emitting unit 20. The first light-emitting element(s) 11 and the second light-emitting elements 21 are, for example, light-emitting diodes (LEDs) that receive the electric current supplied from the power supply 30 to emit light. The power supply 30 is connected between a first wiring line 51 and a second wiring line 52. Electric power from the power supply 30 is supplied to the first light-emitting element(s) 11 and the second light-emitting elements 21 through the first wiring line 51. A forward direction of each of the first light-emitting element(s) 11 and the second light-emitting elements 21 is a direction from the first wiring line 51 toward the second wiring line 52. When the first light-emitting element(s) 11 and the second light-emitting elements 21 are caused to emit light, the potential of the first wiring line 51 is higher than the potential of the second wiring line 52.

The power supply 30 includes, for example, a battery 31 and a booster circuit 32 that boosts the voltage of the battery 31. It is noted that the light source 1 need not be a battery-driven type of device, and the power supply 30 need not include the battery 31.

The driver 40 causes the first light-emitting element(s) 11 and the second light-emitting elements 21 to emit light at predetermined brightnesses. The phrase “causing the first light-emitting element(s) 11 and the second light-emitting elements 21 to emit light at predetermined brightnesses” refers to controlling the total current value of the first light-emitting element(s) 11 and the total current value of the second light-emitting elements 21 to be predetermined values.

The driver 40 includes, for example, a switch unit and a current value control unit. The switch unit performs on/off operation to connect/disconnect the second wiring line 52 and each of the first light-emitting unit 10 and the second light-emitting unit 20. Such on/off control of the switch unit allows a pulse current to be supplied to each of the first light-emitting element(s) 11 and the second light-emitting elements 21. The current value control unit controls, for example, the peak value (amplitude) of the pulse current supplied to each of the first light-emitting element(s) 11 and the second light-emitting elements 21.

For example, the driver 40 uses the switch unit to control the first duty cycle Duty1 for the first light-emitting element(s) 11 and the second duty cycle Duty2 for the second light-emitting elements 21. The duty cycle is a ratio of an ON time to (i.e., divided by) a period of an ON-and-OFF cycle, of a current or a voltage supplied to each of the first light-emitting element(s) 11 and the second light-emitting elements 21. There may be a case in which the duty cycle is 1 (lighting control by a continuous current or voltage).

For example, during a predetermined period in which the first light-emitting element(s) 11 is (are) to be turned on, a pulse current is supplied to the first light-emitting element(s) 11, and the first light-emitting element(s) 11 is (are) repeatedly turned on and off in predetermined cycles. When the cycle is sufficiently short, the lighting appears to be continuous to human eyes. Alternatively, during a predetermined period in which the first light-emitting element(s) 11 is (are) to be lit, a continuous current (direct current) may be supplied to the first light-emitting element(s) 11 to cause the first light-emitting element(s) 11 to be lit. Similarly, during a predetermined period in which the second light-emitting elements 21 are to be lit, a pulse current or a continuous current may be supplied to light the second light-emitting elements 21.

In the example illustrated in FIG. 1, the first light-emitting unit 10 and the second light-emitting unit 20 are connected to the same common driver 40, but the first light-emitting unit 10 and the second light-emitting unit 20 may be connected to different control units.

A first light emission peak wavelength of the first light-emitting element 11 is different from a second light emission peak wavelength of the second light-emitting element 21. The first light emission peak wavelength of the first light-emitting element 11 is, for example, in a range from 430 nm to less than 490 nm, and the first light-emitting element 11 mainly emits blue light. The second light emission peak wavelength of the second light-emitting element 21 is, for example, in a range from 490 nm to less than 570 nm, and the second light-emitting element 21 mainly emits green light.

A second forward voltage Vf2 of one of the one or more second light-emitting elements 21 is lower than a first forward voltage Vf1 of one of the one or more first light-emitting elements 11. With a structure in which the common power supply 30 drives the first light-emitting element(s) 11 and the second light-emitting elements 21 having different forward voltages, the light source 1 that is small and inexpensive can be provided, compared to a case in which the first light-emitting element(s) 11 and the second light-emitting elements 21 are driven by different power supplies.

A first voltage V1, which is the forward voltage of the first light-emitting unit 10, and a second voltage V2, which is the forward voltage of the second light-emitting unit 20, are different from each other. The first voltage V1 is the product (i.e., multiplication) of the first forward voltage Vf1 of the first light-emitting element 11 and the number of series-connected first light-emitting elements 11 in the first light-emitting unit 10 (which may be one). The second voltage V2 is the product of the second forward voltage Vf2 of the second light-emitting element 21 and the number of the series-connected second light-emitting elements 21 in the second light-emitting unit 20.

According to the present embodiment, the second light-emitting unit 20 includes the second light-emitting elements 21 having the second forward voltage Vf2 lower than the first forward voltage Vf1 of the first light-emitting element 11, and the number of the series-connected second light-emitting elements 21 in the second light-emitting unit 20 is greater than the number of series-connected first light-emitting elements 11 in the first light-emitting unit 10. With this structure, compared to a case in which the number of the series-connected second light-emitting elements 21 is equal to the number of series-connected first light-emitting elements 11, the difference between the first voltage V1 of the first light-emitting unit 10 and the second voltage V2 of the second light-emitting unit 20 can be reduced. The absolute value of difference between the first voltage V1 of the first light-emitting unit 10 and the second voltage V2 of the second light-emitting unit 20 is lower than the second forward voltage Vf2 of the second light-emitting element 21. With this configuration, it is possible to reduce a loss of power from the power supply 30 due to the difference between the first voltage V1 of the first light-emitting unit 10 and the second voltage V2 of the second light-emitting unit 20, and thus to reduce power consumption of the light source 1. For example, when the first voltage V1 of the first light-emitting unit 10 is higher than the second voltage V2 of the second light-emitting unit 20, the power supply 30 is set to provide a voltage equal to or higher than the first voltage V1 which is a voltage required to cause the first light-emitting unit 10 to be turned on. The set voltage of the power supply 30 is higher than the second voltage V2, which is a voltage required to cause the second light-emitting unit 20 to be turned on, and thus power loss due to a difference between the set voltage of the power supply 30 and the second voltage V2 of the second light-emitting unit 20 tends to occur. In the present embodiment, the difference between the first voltage V1 of the first light-emitting unit 10 and the second voltage V2 of the second light-emitting unit 20 can be reduced. Thus, the difference between the set voltage of the power supply 30 and the second voltage V2 of the second light-emitting unit 20 can be reduced, so that power consumption of the light source 1 can be reduced. For example, the absolute value of difference between the first voltage V1 of the first light-emitting unit 10 and the second voltage V2 of the second light-emitting unit 20 is preferably equal to or less than 2 V.

### First Comparative Example

A light source of a first comparative example includes eight first light-emitting units 10 and eight second light-emitting units 20 connected in parallel to each other with respect to the power supply 30. The number of series-connected first light-emitting elements 11 in each of the first light-emitting units 10 is 14 and the number of series-connected second light-emitting elements 21 in each of the second light-emitting units 20 is 14. Therefore, the light source includes a total of 112 first light-emitting elements 11 and a total of 112 second light-emitting elements 21.

In the first comparative example, the first forward voltage Vf1 of the first light-emitting element 11 is 2.74 V, the second forward voltage Vf2 of the second light-emitting element 21 is 2.31 V, the first voltage V1 of the first light-emitting unit 10 is 38.36 V, and the second voltage V2 of the second light-emitting unit 20 is 32.34 V. Thus, the absolute value of difference between the first voltage V1 and the second voltage V2 is 6.02 V.

### First Implementation Example

In a light source of a first implementation example, the total number of the first light-emitting elements 11 (112), the total number of the second light-emitting elements 21 (112), the number of the first light-emitting units 10 connected in parallel to each other with respect to the power supply 30 (8), the number of the series-connected first light-emitting elements 11 in each of the first light-emitting units 10 (14), the first forward voltage Vf1 of the first light-emitting element 11 (2.74 V), the second forward voltage Vf2 of the second light-emitting element 21 (2.31 V), and the first voltage V1 of the first light-emitting unit 10 (38.36 V) are the same as those in the first comparative example.

In the first implementation example, the number of series-connected second light-emitting elements 21 in each of the second light-emitting units 20 is 16, which is larger than the number of series-connected first light-emitting elements 11 in each of the first light-emitting units 10 (14). In addition, the number of the second light-emitting units 20 connected in parallel to each other with respect to the power supply 30 is 7. In the first implementation example, the second voltage V2 of the second light-emitting unit 20 is 36.96 V (=2.31×16). Therefore, the absolute value of the difference between the first voltage V1 and the second voltage V2 in the first implementation example can be 1.4 V, which is smaller than the absolute value of the difference between the first voltage V1 and the second voltage V2 in the first comparative example (6.02 V). As a result, the light source of the first implementation example can reduce power consumption compared to the light source of the first comparative example.

### Second Comparative Example

A light source of a second comparative example includes six first light-emitting units 10 and six second light-emitting units 20 connected in parallel to each other with respect to the power supply 30. The number of series-connected first light-emitting elements 11 in each of the first light-emitting units 10 is 15 and the number of series-connected second light-emitting elements 21 in each of the second light-emitting units 20 is 15. Therefore, the light source includes a total of 90 first light-emitting elements 11 and a total of 90 second light-emitting elements 21.

In the second comparative example, the first forward voltage Vf1 of the first light-emitting element 11 is 2.79 V, the second forward voltage Vf2 of the second light-emitting element 21 is 2.41 V, the first voltage V1 of the first light-emitting unit 10 is 41.85 V, and the second voltage V2 of the second light-emitting unit 20 is 36.15 V. Thus, the absolute value of difference between the first voltage V1 and the second voltage V2 is 5.70 V.

### Second Implementation Example

In a light source of a second implementation example, the total number of the first light-emitting elements 11 (90), the total number of the second light-emitting elements 21 (90), the number of the first light-emitting units 10 connected in parallel to each other with respect to the power supply 30 (6), the number of the series-connected first light-emitting elements 11 in each of the first light-emitting units 10 (15), the first forward voltage Vf1 of the first light-emitting element 11 (2.79 V), the second forward voltage Vf2 of the second light-emitting element 21 (2.41 V), and the first voltage V1 of the first light-emitting unit 10 (41.85 V) are the same as those in the second comparative example.

In the second implementation example, the number of series-connected second light-emitting elements 21 in each of the second light-emitting units 20 is 18, which is larger than the number of series-connected first light-emitting elements 11 in each of the first light-emitting units 10 (15). In addition, the number of the second light-emitting units 20 connected in parallel to each other with respect to the power supply 30 is 5. In the second implementation example, the second voltage V2 of the second light-emitting unit 20 is 43.38 V (=2.41×18). Therefore, the absolute value of the difference between the first voltage V1 and the second voltage V2 in the second implementation example can be 1.53 V, which is smaller than the absolute value of the difference between the first voltage V1 and the second voltage V2 in the second comparative example (5.70 V). As a result, the light source of the second implementation example can reduce power consumption compared to the light source of the second comparative example.

In the light source of the present embodiment, the voltage values, the number of light-emitting elements, the number of series connections, and the number of parallel connections are not limited to those specified in the first and second implementation examples.

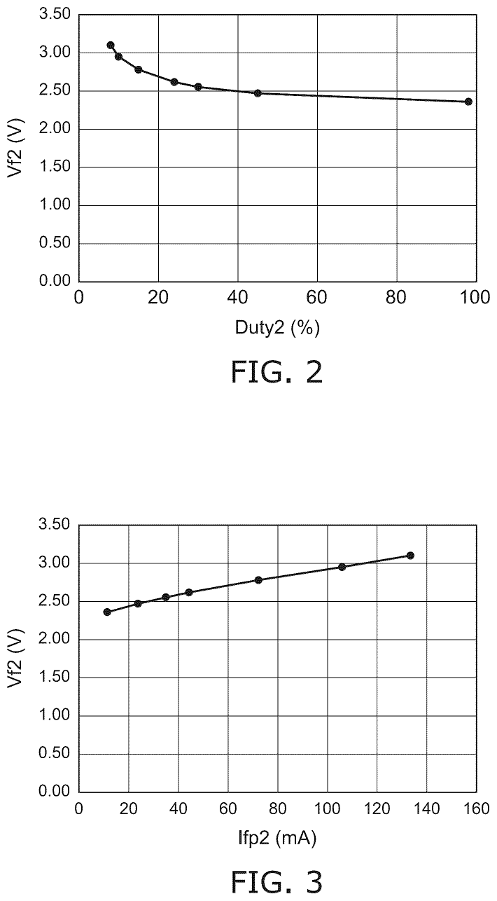

FIG. 2 is a graph of measurement data showing a relationship between the second duty cycle Duty2 and the second forward voltage Vf2 for the second light-emitting element 21 at a predetermined total current value. A lower second duty cycle Duty2 results in a higher second forward voltage Vf2. Similarly, in the first light-emitting element 11, a lower first duty cycle Duty1 results in a higher first forward voltage Vf1.

Therefore, in a case in which the second voltage V2 of the second light-emitting unit 20 is lower than the first voltage V1 of the first light-emitting unit 10 (for example, as in the first implementation example), the driver 40 preferably controls the first duty cycle Duty1 for the first light-emitting element 11 and the second duty cycle Duty2 for the second light-emitting element 21 such that the second duty cycle Duty2 is lower than the first duty cycle Duty1. This makes it possible to increase the second voltage V2 of the second light-emitting unit 20 so as to reduce the absolute value of difference between the first voltage V1 and the second voltage V2, so that the power consumption of the light source can be reduced.

In contrast, in a case in which the first voltage V1 of the first light-emitting unit 10 is lower than the second voltage V2 of the second light-emitting unit 20 (for example, as in the second implementation example), the driver 40 preferably controls the first duty cycle Duty1 for the first light-emitting element 11 and the second duty cycle Duty2 for the second light-emitting element 21 such that the first duty cycle Duty1 is lower than the second duty cycle Duty2. This makes it possible to increase the first voltage V1 of the first light-emitting unit 10 so as to reduce the absolute value of difference between the first voltage V1 and the second voltage V2, so that the power consumption of the light source can be reduced.

The driver 40 controls each of the first light-emitting element(s) 11 and the second light-emitting elements 21 such that it has a predetermined brightness, in other words, a predetermined total current value. To maintain a predetermined total current value (to prevent the total current value from deviating from a predetermined value), the driver 40 increases a pulse forward current (the amplitude of the pulse or the peak current value) Ifp when the duty cycle (the ratio of an ON time to a period of a cycle) is decreased. An increase in the pulse forward current Ifp results in an increase in the temperature of the light-emitting element and thus a higher risk of failure of the light-emitting element.

FIG. 3 is a graph of measurement data showing a relationship between a second pulse forward current Ifp2 and the second forward voltage Vf2 for the second light-emitting element 21 at a predetermined total current value. A higher second forward voltage Vf2 results in a higher second pulse forward current Ifp2. As described above with reference to FIG. 2, a lower second duty cycle Duty2 results in a higher second forward voltage Vf2. Therefore, a lower second duty cycle Duty2 results in a higher second pulse forward current Ifp2. Similarly, in the first light-emitting element 11, a lower first duty cycle Duty1 results in a higher first pulse forward current Ifp1.

In a case in which the second voltage V2 of the second light-emitting unit 20 is lower than the first voltage V1 of the first light-emitting unit 10 and the second duty cycle Duty2 for the second light-emitting element 21 is lower than the first duty cycle Duty1 for the first light-emitting element 11, the second pulse forward current Ifp2 of the second light-emitting element 21 tends to be high. In this case, a second total current value of the second light-emitting elements 21 is preferably smaller than a first total current value of the first light-emitting element(s) 11. This makes it possible to prevent the second pulse forward current Ifp2 of the second light-emitting element 21 from becoming excessively high, and thus to reduce the temperature rise of the second light-emitting element 21 and the risk of failure of the second light-emitting element 21.

In a case in which the first voltage V1 of the first light-emitting unit 10 is lower than the second voltage V2 of the second light-emitting unit 20 and the first duty cycle Duty1 for the first light-emitting element 11 is lower than the second duty cycle Duty2 for the second light-emitting element 21, the first pulse forward current Ifp1 of the first light-emitting element 11 tends to be high. In this case, the first total current value of the first light-emitting element(s) 11 is preferably smaller than the second total current value of the second light-emitting elements 21. This makes it possible to prevent the first pulse forward current Ifp1 of the first light-emitting element 11 from becoming excessively high, and thus to reduce the temperature rise of the first light-emitting element 11 and the risk of failure of the first light-emitting element 11.

When the second duty cycle Duty2 is set lower than the first duty cycle Duty1 (the second duty cycle Duty2<the first duty cycle Duty1), the first duty cycle Duty1 is preferably equal to or less than 20 times the second duty cycle Duty2. Such a duty cycle makes it possible to prevent the first pulse forward current Ifp1 of the first light-emitting element 11 from becoming excessively high. When the first duty cycle Duty1 is set lower than the second duty cycle Duty2 (the first duty cycle Duty1<the second duty cycle Duty2), the second duty cycle Duty2 is preferably equal to or less than 20 times the first duty cycle Duty1. Such a duty cycle makes it possible to prevent the second pulse forward current Ifp2 of the second light-emitting element 21 from becoming excessively high.

As illustrated in FIG. 4, the light source 1 according to an embodiment includes the substrate 200 and a plurality of light-emitting devices 100. Each of the light-emitting devices 100 includes the first light-emitting element 11 and the second light-emitting element 21. The substrate 200 supports the light-emitting devices 100. The substrate 200 is a wiring substrate that supplies power from the power supply 30 to the first light-emitting elements 11 and the second light-emitting elements 21. The substrate 200 includes an insulating base body 102 and a wiring portion disposed at least on an upper surface of the insulating base body 102. The first light-emitting elements 11 and the second light-emitting elements 21 are electrically connected to the wiring portion. The configuration of the light-emitting device 100 will be described in detail below.

On the substrate 200, the plurality of light-emitting devices 100 are arranged in the first direction X. In the present embodiment, each of the light-emitting devices 100 includes one first light-emitting element 11 and one second light-emitting element 21, for example. In each of the light-emitting devices 100, the first light-emitting element 11 and the second light-emitting element 21 are arranged in the second direction Y. With the first light-emitting element 11 and the second light-emitting element 21 that are arranged in the second direction Y in the light-emitting device 100, the sizes of the light-emitting device 100 and the light source 1 can be reduced in the first direction X.

When the above-mentioned duty cycle is high, the ON time during which current is supplied to the light-emitting element is long, and thus the temperature of the light-emitting element tends to increase. Therefore, in the light-emitting device 100, when the first duty cycle Duty1 for the first light-emitting element 11 is higher than the second duty cycle Duty2 for the second light-emitting element 21, the first light-emitting element 11 is preferably located between the substrate 200 and the second light-emitting element 21 in the second direction Y. In such an arrangement, the first light-emitting element 11 is located closer to the substrate 200 than the second light-emitting element 21 in the second direction Y. In other words, the shortest distance from the first light-emitting element 11 to the substrate 200 in the second direction Y is shorter than the shortest distance from the second light-emitting element 21 to the substrate 200 in the second direction Y. This facilitates dissipation of the heat generated by the first light-emitting element 11, whose temperature tends to increase compared to that of the second light-emitting element 21 due to the high duty cycle, to the substrate 200. As a result, temperature rise in the first light-emitting element 11 can be reduced, so that the risk of failure of the first light-emitting element 11 can be reduced.

In the light-emitting device 100, when the second duty cycle Duty2 for the second light-emitting element 21 is higher than the first duty cycle Duty1 for the first light-emitting element 11, the second light-emitting element 21 is preferably located between the substrate 200 and the first light-emitting element 11 in the second direction Y. In such an arrangement, the second light-emitting element 21 is located closer to the substrate 200 than the first light-emitting element 11 in the second direction Y. In other words, the shortest distance from the second light-emitting element 21 to the substrate 200 in the second direction Y is shorter than the shortest distance from the first light-emitting element 11 to the substrate 200 in the second direction Y. This facilitates dissipation of the heat generated by the second light-emitting element 21, whose temperature tends to increase compared with that of the first light-emitting element 11 due to the high duty cycle, to the substrate 200. As a result, temperature rise in the second light-emitting element 21 can be reduced, and the risk of failure of the second light-emitting element 21 can be reduced.

In addition, when the total current value is high, the temperature of the light-emitting element tends to increase. Therefore, of the first light-emitting element 11 and the second light-emitting element 21, the light-emitting element having a larger total current value is preferably located closer to the substrate 200 in the second direction Y than the light-emitting element having a lower total current value. This makes it possible to reduce temperature rise in the light-emitting element having the larger total current value.

In the first and second implementation examples described above, a plurality of the first light-emitting units 10 are connected in parallel to each other with respect to the power supply 30, and in each of the first light-emitting units 10, the number of the first light-emitting elements 11 connected in series is larger than the number of the plurality of first light-emitting units 10 connected in parallel. Increasing the number of the first light-emitting elements 11 connected in series in the first light-emitting unit 10 allows for reducing variation, among the plurality of first light-emitting elements 11, in value of current flowing through each of the plurality of first light-emitting elements 11 connected in series. This makes it possible to easily reduce luminance variation of the plurality of first light-emitting elements 11 which are emitting light. Moreover, with the configuration in which a larger number of first light-emitting elements 11 are connected in series between the power supply 30 and the driver 40 and the driver 40 controls the larger number of first light-emitting elements 11 to emit light, the complexity of the layout of the wiring portion in the substrate 200 can be reduced. In addition, reducing the number of the plurality of first light-emitting units 10 connected in parallel facilitates reduction of the complexity of the layout of the wiring portion in the substrate 200. By reducing the complexity of the layout of the wiring portion in the substrate 200, the area of the region where the wiring portion is formed in the substrate 200 can be reduced, and reduction in the planar size of the substrate 200 can be facilitated.

Similarly, as described in the first and second implementation examples, a plurality of the second light-emitting units 20 are connected in parallel to each other with respect to the power supply 30, and in each of the second light-emitting units 20, the number of the second light-emitting elements 21 connected in series is preferably larger than the number of the plurality of second light-emitting units 20 connected in parallel.

The first voltage V1 of the first light-emitting unit 10 is obtained by the first forward voltage Vf1 of the first light-emitting element 11×Ns, where the electrical resistance of the wiring line or the like are ignored and Ns is the number of the first light-emitting elements 11 connected in series in the first light-emitting unit 10. Thus, the larger the number of series-connected first light-emitting elements 11 Ns is, the higher the first voltage V1 is. When the number of the first light-emitting units 10 connected in parallel each including Ns first light-emitting elements 11 connected in series is Np, the same first voltage V1 is applied to each of the Np first light-emitting units 10. Even if the number of parallel-connected first light-emitting units 10 Np is increased while the number of series-connected light-emitting elements 11 Ns remains constant, the first voltage V1 does not increase. If an electrical open failure (conduction failure) occurs in any one of the plurality of first light-emitting elements 11 connected in series in the first light-emitting unit 10, the first light-emitting unit 10 including the first light-emitting element 11 having the open failure cannot be lit. In the light source 1 in which the number of parallel-connected first light-emitting units 10 Np is large, even if there is an open failure in any of the first light-emitting elements 11 in any of the first light-emitting units 10, the other first light-emitting units 10 can be lit, and thus the total number of first light-emitting elements 11 that do not emit light can be easily reduced. As a result, reduction of the brightness of the light source 1 may be suppressed even if there is an open failure in any of the first light-emitting elements 11 in any of the first light-emitting units 10. The above description also applies to the second light-emitting units 20 and the second light-emitting elements 21.

As illustrated in FIG. 1, the second light-emitting units 20 include a first one 20A of the second light-emitting units and a second one 20B of the second light-emitting units that are connected in parallel to each other with respect to the power supply 30. Each of the first one 20A of the second light-emitting units and the second one 20B of the second light-emitting units includes a plurality of second light-emitting elements 21 connected in series. The second light-emitting elements 21 included in the first one 20A of the second light-emitting units are referred to as second light-emitting elements 21A. The second light-emitting elements 21 included in the second one 20B of the second light-emitting units are referred to as second light-emitting elements 21B.

As illustrated in FIG. 4, in the first direction X in which the plurality of light-emitting devices 100 are arranged, a second light-emitting element 21B of the second one 20B of the second light-emitting units is located between two of the second light-emitting elements 21A of the first one 20A of the second light-emitting units. With this arrangement, even if the second light-emitting element 21B of the second one 20B of the second light-emitting units cannot emit light due to an electrical open failure (non-conduction failure) or the like, the second light-emitting elements 21A of the first one 20A of the second light-emitting units, which are adjacent to that second light-emitting element 21B in the first direction X, can emit light, so that the non-emitting portions can be inhibited from being unevenly positioned. This can facilitate reduction in luminance unevenness in the light source 1.

In the first direction X, the second light-emitting element 21A of the first one 20A of the second light-emitting units is located between two of the second light-emitting elements 21B of the second one 20B of the second light-emitting units. Even if the second light-emitting element 21A of the first one 20A of the second light-emitting units does not emit light due to an electrical open failure or the like, the second light-emitting elements 21B of the second one 20B of the second light-emitting units, which are adjacent to that second light-emitting element 21A in the first direction X, emit light, so that the non-emitting portions can be inhibited from being unevenly positioned. This can facilitate reduction in luminance unevenness in the light source 1.

As illustrated in FIG. 1, the first light-emitting units 10 include a first one 10A of the first light-emitting units and a second one 10B of the first light-emitting units that are connected in parallel to each other with respect to the power supply 30. Each of the first one 10A of the first light-emitting units and the second one 10B of the first light-emitting units includes a plurality of first light-emitting elements 11 connected in series. The first light-emitting elements 11 included in the first one 10A of the first light-emitting units are referred to as first light-emitting elements 11A. The first light-emitting elements 11 included in the second one 10B of the first light-emitting units are referred to as first light-emitting elements 11B.

As illustrated in FIG. 4, in the first direction X in which the plurality of light-emitting devices 100 are arranged, the first light-emitting element 11B of the second one 10B of the first light-emitting units is located between two of the first light-emitting elements 11A of the first one 10A of the first light-emitting units. Even if the first light-emitting element 11B of the second one 10B of the first light-emitting units does not emit light due to an electrical open failure or the like, the first light-emitting elements 11A of the first one 10A of the first light-emitting units, which are adjacent to that first light-emitting element 11B in the first direction X, can emit light, so that the non-emitting portions can be inhibited from being unevenly positioned. This makes it possible to easily reduce luminance unevenness in the light source 1.

In the first direction X, the first light-emitting element 11A of the first one 10A of the first light-emitting units is located between two of the first light-emitting elements 11B of the second one 10B of the first light-emitting units. With this arrangement, even if the first light-emitting element 11A of the first one 10A of the first light-emitting units does not emit light due to an electrical open failure or the like, the first light-emitting elements 11B of the second one 10B of the first light-emitting units, which are adjacent to that first light-emitting element 11A in the first direction X, can emit light, so that non-emitting portions can be inhibited from being unevenly positioned. This can facilitate reduction in luminance unevenness in the light source 1.

### Light-Emitting Device

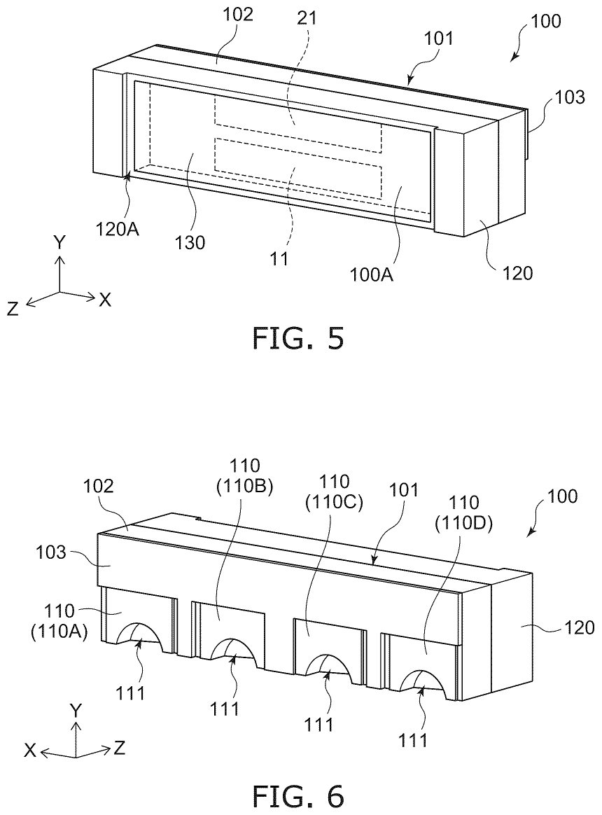

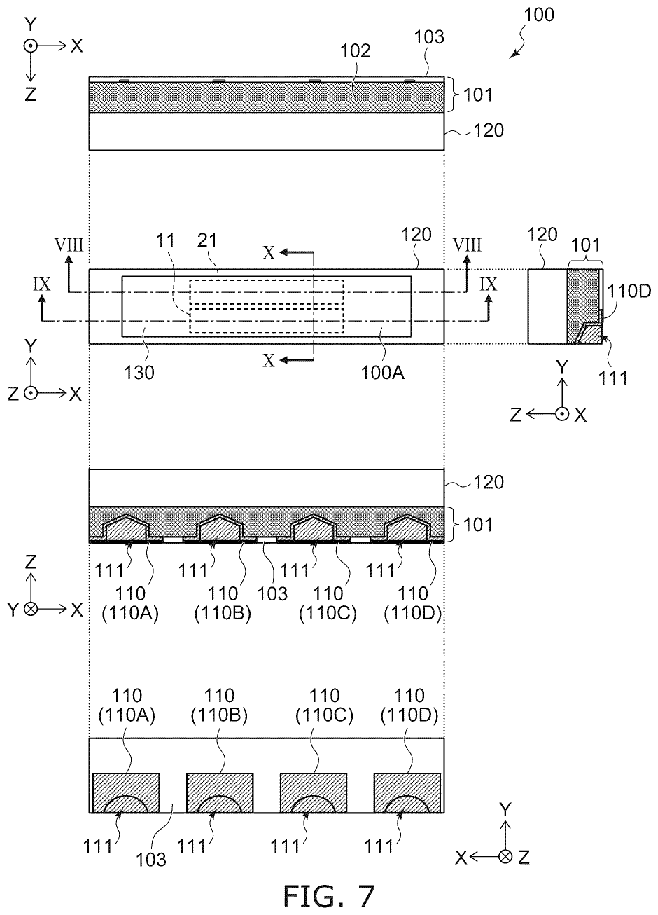

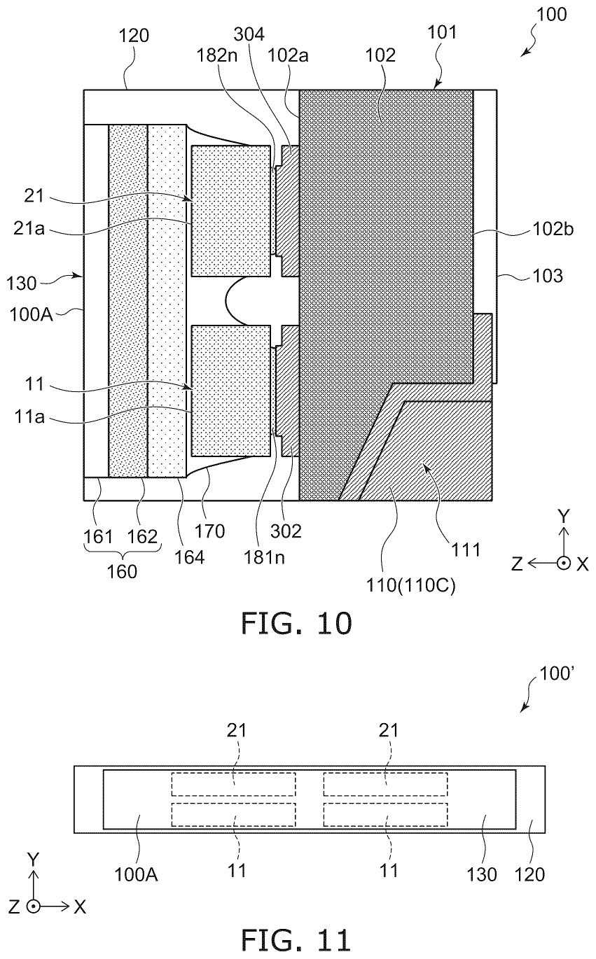

An example configuration of the light-emitting device 100 will be described in detail with reference to FIGS. 5 to 10.

The light-emitting device 100 has a substantially rectangular parallelepiped shape elongated in the first direction X. The light-emitting device 100 has a light-emitting surface 100A parallel to the XY plane. The light-emitting surface 100A has a rectangular shape in which the length in the first direction X is longer than the length in the second direction Y.

The light-emitting device 100 includes the first light-emitting element 11, the second light-emitting element 21, a support member 101, a light-reflective member 120, and a light-transmissive member 130.

First Light-emitting Element, Second Light-emitting Element Each of the first light-emitting element 11 and the second light-emitting element 21 includes a semiconductor structure. The semiconductor structure includes an n-side semiconductor layer, a p-side semiconductor layer, and an active layer located between the n-side semiconductor layer and the p-side semiconductor layer. The active layer may have a single quantum well (SQW) structure, or may have a multi quantum well (MQW) structure including a plurality of well layers. The semiconductor structure includes a plurality of semiconductor layers each made of a nitride semiconductor. The nitride semiconductor encompasses all semiconductors having compositions represented by a chemical formula of InₓAl_{y}Ga_{1-x-y}N (0≤x, 0≤y, and x+y≤1), where composition ratios x and y are varied within respective ranges.

The semiconductor structure may include a plurality of active layers. When the semiconductor structure includes the plurality of active layers, the plurality of active layers may have the same light emission peak wavelength or different light emission peak wavelengths. It is noted that having the same light emission peak wavelength includes a case in which there is a variation of about a few nm. Any suitable combination of different light emission peak wavelengths of the plurality of active layers can be used.

Each of the first light-emitting element 11 and the second light-emitting element 21 may include an element substrate. The semiconductor structure is formed on an element substrate such as a sapphire substrate, for example.

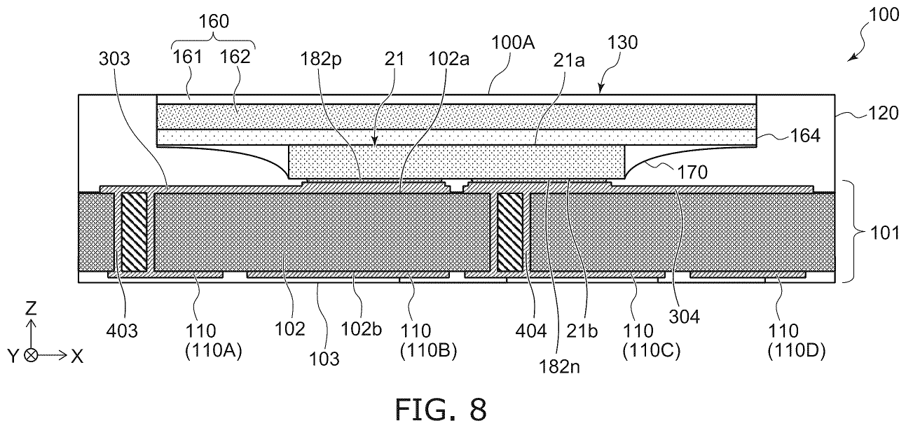

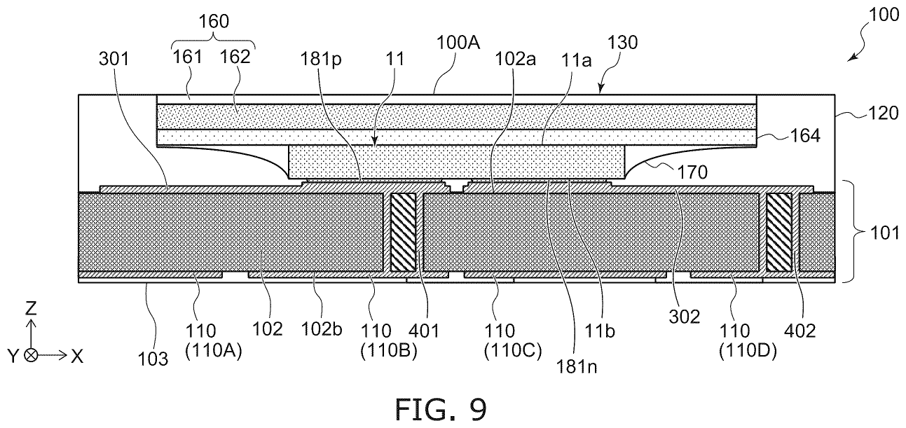

As illustrated in FIG. 9, the first light-emitting element 11 has an element light-emitting surface 11a and a mounting surface 11b opposite to the element light-emitting surface 11a. On the mounting surface 11b of the first light-emitting element 11, a positive electrode 181p electrically connected to the p-side semiconductor layer of the first light-emitting element 11 and a negative electrode 181n electrically connected to the n-side semiconductor layer of the first light-emitting element 11 are disposed. As illustrated in FIG. 8, the second light-emitting element 21 has an element light-emitting surface 21a and a mounting surface 21b opposite to the element light-emitting surface 21a. On the mounting surface 21b of the second light-emitting element 21, a positive electrode 182p electrically connected to the p-side semiconductor layer of the second light-emitting element 21 and a negative electrode 182n electrically connected to the n-side semiconductor layer of the second light-emitting element 21 are disposed.

### Support Member

The support member 101 supports the first light-emitting element 11, the second light-emitting element 21, the light-reflective member 120, and the light-transmissive member 130.

The support member 101 includes the insulating base body 102. The insulating base body 102 is made of, for example, resin, ceramic, glass, or the like. The insulating base body 102 may be made of a composite material such as a fiber-reinforced resin, for example, a glass epoxy substrate. Examples of the resin from which the insulating base body 102 is made include bismaleimide-triazine (BT) resins, epoxy resins, and polyimide resins. Examples of the ceramic from which the insulating base body 102 is made include aluminum oxide, aluminum nitride, zirconium oxide, zirconium nitride, titanium oxide, titanium nitride, and mixtures of two or more of these materials. Among these ceramics, it is advantageous to use a material having a coefficient of linear thermal expansion close to those of the first light-emitting element 11 and the second light-emitting element 21 as the material of the insulating base body 102. The insulating base body 102 has a first surface 102a and a second surface 102b opposite to the first surface 102a.

The support member 101 includes external connection terminals 110 for electrically connecting the light-emitting device 100 to the substrate 200 illustrated in FIG. 4. The external connection terminals 110 are arranged on the second surface 102b of the insulating base body 102. The external connection terminals 110 face the upper surface of the substrate 200 illustrated in FIG. 4 in the second direction Y. The external connection terminals 110 include a first external connection terminal 110A, a second external connection terminal 110B, a third external connection terminal 110C, and a fourth external connection terminal 110D. The first external connection terminal 110A, the second external connection terminal 110B, the third external connection terminal 110C, and the fourth external connection terminal 110D are arranged in the first direction X. The first external connection terminal 110A and the fourth external connection terminal 110D are located at both ends in the first direction X. In the first direction X, the second external connection terminal 110B and the third external connection terminal 110C are located between the first external connection terminal 110A and the fourth external connection terminal 110D. In the first direction X, the second external connection terminal 110B is adjacent to the first external connection terminal 110A, and the third external connection terminal 110C is located between the second external connection terminal 110B and the fourth external connection terminal 110D. In the first direction X, the first external connection terminal 110A and the second external connection terminal 110B are spaced apart from each other, the second external connection terminal 110B and the third external connection terminal 110C are spaced apart from each other, and the third external connection terminal 110C and the fourth external connection terminal 110D are spaced apart from each other.

An insulating layer 103 for preventing a short-circuit between two adjacent external connection terminals 110 is disposed in the back surface of the light-emitting device 100.

The support member 101 further includes a first conductive portion 301, a second conductive portion 302, a third conductive portion 303, a fourth conductive portion 304, a first connection portion 401, a second connection portion 402, a third connection portion 403, and a fourth connection portion 404. The first conductive portion 301, the second conductive portion 302, the third conductive portion 303, and the fourth conductive portion 304 are disposed on the first surface 102a of the insulating base body 102. The first connection portion 401, the second connection portion 402, the third connection portion 403, and the fourth connection portion 404 each extend through the insulating base body 102 from the first surface 102a to the second surface 102b.

As illustrated in FIG. 9, the positive electrode 181p of the first light-emitting element 11 is bonded onto the first conductive portion 301 and electrically connected to the first conductive portion 301. The negative electrode 181n of the first light-emitting element 11 is bonded onto the second conductive portion 302 and electrically connected to the second conductive portion 302. The first connection portion 401 electrically connects the first conductive portion 301 and the second external connection terminal 110B. The second connection portion 402 electrically connects the second conductive portion 302 and the fourth external connection terminal 110D. The positive electrode 181p of the first light-emitting element 11 is electrically connected to the second external connection terminal 110B via the first conductive portion 301 and the first connection portion 401. The negative electrode 181n of the first light-emitting element 11 is electrically connected to the fourth external connection terminal 110D via the second conductive portion 302 and the second connection portion 402.

As illustrated in FIG. 8, the positive electrode 182p of the second light-emitting element 21 is bonded onto the third conductive portion 303 and electrically connected to the third conductive portion 303. The negative electrode 182n of the second light-emitting element 21 is bonded onto the fourth conductive portion 304 and electrically connected to the fourth conductive portion 304. The third connection portion 403 electrically connects the third conductive portion 303 and the first external connection terminal 110A. The fourth connection portion 404 electrically connects the fourth conductive portion 304 and the third external connection terminal 110C. The positive electrode 182p of the second light-emitting element 21 is electrically connected to the first external connection terminal 110A via the third conductive portion 303 and the third connection portion 403. The negative electrode 182n of the second light-emitting element 21 is electrically connected to the third external connection terminal 110C via the fourth conductive portion 304 and the fourth connection portion 404.

Each of the first external connection terminal 110A, the second external connection terminal 110B, the third external connection terminal 110C, and the fourth external connection terminal 110D has a recessed portion 111. Each of the recessed portions 111 opens to the lower surface side and the back surface side of the light-emitting device 100. The lower surface of the light-emitting device 100 faces the upper surface of the substrate 200 illustrated in FIG. 4. The back surface of the light-emitting device 100 is opposite to the light-emitting surface 100A in the third direction Z. In a plan view of the back surface of the light-emitting device 100, the shape of the recessed portion 111 is, for example, a semicircular shape. A conductive bonding member 150, such as solder, illustrated in FIG. 4 is disposed in each of the recessed portions 111.

The external connection terminals 110 may be made of copper, iron, nickel, tungsten, chromium, aluminum, silver, platinum, gold, titanium, palladium, rhodium, or an alloy containing one or more thereof, for example. For enhancing heat dissipation, the external connection terminals 110 are preferably made of copper or a copper alloy. The external connection terminals 110 may each be a single layer film or a multilayer film of any of the above-mentioned metal materials. When the outermost surface of each of the external connection terminals 110 is made of silver, platinum, aluminum, rhodium, gold, or an alloy containing one or more of these metals, excellent wetting of the bonding member 150 such as solder to the external connection terminal 110 can be achieved.

As illustrated in FIG. 4, each of the light-emitting devices 100 is disposed on the upper surface of the substrate 200 such that the light-emitting surface 100A faces the positive direction of the Z-axis and the lower surface of the light-emitting device 100 faces the upper surface of substrate 200. The bonding members 150 each disposed in the recessed portion 111 of the external connection terminal 110 are bonded to the wiring portion disposed on the upper surface of the substrate 200. The first light-emitting element 11 and the second light-emitting element 21 are electrically connected to the wiring portion of the substrate 200 via the external connection terminals 110 and the bonding members 150.

The light source 1 according to the present embodiment can be used as a light source for a backlight of a liquid crystal display device, for example. Light emitted from the light-emitting surface 100A of the light-emitting device 100 is incident on a lateral surface of a light guide plate in the backlight. The light-emitting device 100 emits, from the light-emitting surface 100A, mixed light (for example, white light) of light emitted by the first light-emitting element 11, light emitted by the second light-emitting element 21, and light generated by wavelength conversion by the light-transmissive member 130 described later.

In the plan view of the light-emitting surface 100A, each of the first light-emitting element 11 and the second light-emitting element 21 has a rectangular shape in which the length in the first direction X is longer than the length in the second direction Y. As described above, the first light-emitting element 11 and the second light-emitting element 21 are arranged in the second direction Y. The arrangement in which a long side of the first light-emitting element 11 and a long side of the second light-emitting element 21 face each other in the second direction Y tends to reduce unevenness in mixing the light emitted by the first light-emitting element 11 and the light emitted by the second light-emitting element 21, compared to an arrangement in which a short side of the first light-emitting element 11 and a short side of the second light-emitting element 21 face each other in the second direction Y. Thus, such an arrangement can reduce color unevenness in light emitted from the light-emitting device 100.

### Light-Transmissive Member

In the third direction Z, the light-transmissive member 130 faces the element light-emitting surface 11a of the first light-emitting element 11 and the element light-emitting surface 21a of the second light-emitting element 21. The surface of the light-transmissive member 130 opposite to the surface of the light-transmissive member 130 facing the first light-emitting element 11 and the second light-emitting element 21 is the light-emitting surface 100A of the light-emitting device 100.

The light-transmissive member 130 has transmissivity to light emitted by each of the first light-emitting element 11 and the second light-emitting element 21. The light-transmissive member 130 has a transmittance of, for example, 60% or more, preferably 70% or more, more preferably 80% or more, for light having the first light emission peak wavelength of the first light-emitting element 11. The light-transmissive member 130 has a transmittance of, for example, 60% or more, preferably 70% or more, more preferably 80% or more, for light having the second light emission peak wavelength of the second light-emitting element 21.

Since the single light-transmissive member 130 covers both the first light-emitting element 11 and the second light-emitting element 21, the light emitted by the first light-emitting element 11 and the light emitted by the second light-emitting element 21 can be efficiently mixed inside the light-transmissive member 130.

As illustrated in FIGS. 8 to 10, the light-transmissive member 130 may include a protective layer 161 and a wavelength conversion layer 162. In the third direction Z, the wavelength conversion layer 162 is located between the support member 101 and the protective layer 161. The protective layer 161 protects the wavelength conversion layer 162. The wavelength conversion layer 162 includes a phosphor. For example, the phosphor absorbs a part of the light emitted by the first light-emitting element 11 (blue light) and a part of the light emitted by the second light-emitting element 21 (green light) and emits red light. As a result, the light-emitting device 100 can emit white light as a mixture of the red light emitted by the phosphor, the blue light emitted by the first light-emitting element 11 and transmitted through the light-transmissive member 130, and the green light emitted by the second light-emitting element 21 and transmitted through the light-transmissive member 130.

The protective layer 161 and the wavelength conversion layer 162 contain, as their base materials, a silicone resin, a modified silicone resin, an epoxy resin, a modified epoxy resin, a urea resin, a phenol resin, a polycarbonate resin, a trimethylpentene resin, a polynorbornene resin, an acrylic resin, a urethane resin, or a fluororesin, or a resin containing two or more of these resins, for example.

As the phosphor, an yttrium-aluminum-garnet-based phosphor (for example, Y₃(Al,Ga)₅O₁₂: Ce), a lutetium-aluminum-garnet-based phosphor (for example, Lu₃(Al,Ga)₅O₁₂: Ce), a terbium-aluminum-garnet-based phosphor (for example, Tb₃(Al,Ga)₅O₁₂: Ce), a CCA-based phosphor (for example, Ca₁₀(PO₄)₆Cl₂: Eu), a SAE-based phosphor (for example, Sr₄Al₁₄O₂₅: Eu), a chlorosilicate-based phosphor (for example, Ca₈MgSi₄O₁₆Cl₂: Eu), an oxynitride-based phosphor, a nitride-based phosphor, a fluoride-based phosphor, a phosphor having a perovskite structure (for example, CsPb(F,Cl,Br,I)₃), a quantum dot phosphor (for example, CdSe, InP, AgInS₂, or AgInSe₂), or the like can be used. Typical examples of the oxynitride-based phosphor include β-sialon-based phosphors (for example, (Si,Al)₃(O,N)₄: Eu) and α-sialon-based phosphors (for example, Ca(Si,Al)₁₂(O,N)₁₆: Eu). Typical examples of the nitride-based phosphor include SLA-based phosphors (for example, SrLiAl₃N₄: Eu), CASN-based phosphors (for example, CaAlSiN₃: Eu), and SCASN-based phosphors (for example, (Sr,Ca)AlSiN₃: Eu). Typical examples of the fluoride-based phosphor include KSF-based phosphors (for example, K₂SiF₆: Mn), KSAF-based phosphors (for example, K₂Si_{0.99}Al_{0.01}F_{5.99}: Mn), and MGF-based phosphors (for example, 3.5MgO·0.5MgF₂·GeO₂: Mn).

The light-transmissive member 130 may contain one of the above-listed phosphors alone, or may contain two or more of these phosphors. When the light-transmissive member 130 contains two or more of the phosphors, it is beneficial that the distribution of the phosphors in the light-transmissive member 130 is controlled such that the phosphor that emits light with a shorter wavelength is located near the first light-emitting element 11 and the second light-emitting element 21.

The light-transmissive member 130 may further include a light diffusion layer 164. The light diffusion layer 164 is disposed between the first light-emitting element 11 and the wavelength conversion layer 162 and between the second light-emitting element 21 and the wavelength conversion layer 162. The light diffusion layer 164 includes a base material that is the same material as the base materials of the protective layer 161 and the wavelength conversion layer 162, and a light diffusion material. As the light diffusion material, for example, resin particles having a refractive index different from that of the base material, or particles of silicon oxide, aluminum oxide, zirconium oxide, or zinc oxide can be used.

### Light-Reflective Member

In a plan view of the light-emitting surface 100A, the light-reflective member 120 surrounds the light-transmissive member 130, the first light-emitting element 11, and the second light-emitting element 21. The light-reflective member 120 has reflectivity to light emitted by the first light-emitting element 11, light emitted by the second light-emitting element 21, and light emitted by the phosphor. The light-reflective member 120 has a reflectance of 60% or more, preferably 70% or more, and more preferably 80% or more, for the light beams from these sources. The light-reflective member 120 can increase the luminance of the light-emitting device 100 in the front direction (the positive direction of the Z axis).

The light-reflective member 120 includes, for example, a base material and light-scattering particles. As the base material of the light-reflective member 120, a silicone resin, a modified silicone resin, an epoxy resin, a urea resin, a polycarbonate resin, a phenol resin, an acrylic resin, a urethane resin, a fluororesin, or a modified resin thereof, or a resin containing two or more of these resins can be used, for example. The light-scattering particles have a refractive index higher than that of the base material. As the light-scattering particles, particles of titanium oxide, magnesium oxide, zirconium dioxide, potassium titanate, aluminum oxide, aluminum nitride, boron nitride, mullite, niobium oxide, barium sulfate, silicon oxide, an oxide of any of various rare earth elements (for example, yttrium oxide or gadolinium oxide), or the like can be used, for example.

A recessed portion 120A is formed in the front surface of the light-reflective member 120 facing the positive direction of the Z-axis. The light-emitting surface 100A, which is a light-extracting surface of the light-transmissive member 130, is located in the recessed portion 120A of the light-reflective member 120. Thus, the light-emitting surface 100A may be inhibited from being damaged by coming into contact with an external member. In addition, in a state where the light-emitting device 100 is coupled to the light guide plate with the light-emitting surface 100A facing the lateral surface of the light guide plate, an air layer is formed in the recessed portion 120A. The air layer can reduce color unevenness of light emitted from the light-emitting surface 100A.

### Light Guide Member

The light-emitting device 100 may further include a light guide member 170. The light-transmissive member 130 is bonded to the first light-emitting element 11 and the second light-emitting element 21 by the light guide member 170. As the material of the light guide member 170, a resin material including a transparent resin as a base material can be used. As a base material of the light guide member 170, for example, the same material as the base material of the light-transmissive member 130 can be used.

The light guide member 170 includes a portion located between an element lateral surface of the first light-emitting element 11 and the light-reflective member 120. A part of the light emitted by the first light-emitting element 11, which exits from the element lateral surface, may be caused to reflect on the interface between the light guide member 170 and the light-reflective member 120, to be incident on the light-transmissive member 130. The light guide member 170 includes a portion located between an element lateral surface of the second light-emitting element 21 and the light-reflective member 120. A part of the light emitted by the second light-emitting element 21, which exits from the element lateral surface, may be caused to reflect on the interface between the light guide member 170 and the light-reflective member 120, to be incident on the light-transmissive member 130. The light guide member 170 having such a function can improve light extraction efficiency of the light-emitting device 100.

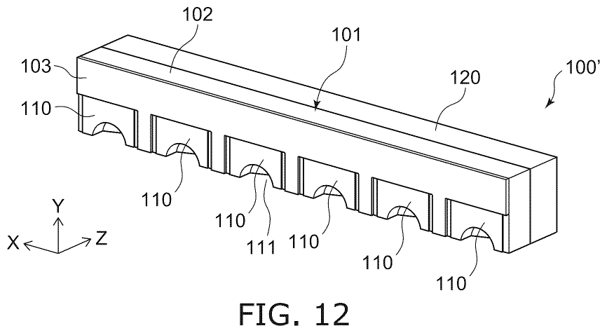

A light-emitting device 100′ according to a modification of the embodiment will be described with reference to FIGS. 11 to 12.

The light-emitting device 100′ according to the modification includes two first light-emitting elements 11 and two second light-emitting elements 21. Two pairs of light-emitting elements, each consisting of one first light-emitting element 11 and one second light-emitting element 21 arranged in the second direction Y, are arranged in the first direction X. The two first light-emitting elements 11 are arranged in the first direction X, and the two second light-emitting elements 21 are arranged in the first direction X. Although the light-reflective member 120 in this example has no recessed portion on the front surface, the recessed portion 120A may be formed on the front surface of the light-reflective member 120 as in the light-emitting device 100 illustrated in FIG. 5.

The light-emitting device 100′ according to the modification includes, for example, six external connection terminals 110. The six external connection terminals 110 of the present embodiment include one external connection terminal 110 electrically connected to the positive electrode of the first light-emitting element 11 located on the +X side and one external connection terminal 110 electrically connected to the positive electrode of the second light-emitting element 21 located on the +X side. The other four external connection terminals 110 include one external connection terminal 110 electrically connected to the negative electrode of the first light-emitting element 11 located on the +X side and the positive electrode of the first light-emitting element 11 located on the −X side, and one external connection terminal 110 electrically connected to the negative electrode of the second light-emitting element 21 located on the +X side and the positive electrode of the second light-emitting element 21 located on the −X side. The remaining two external connection terminals 110 include one external connection terminal 110 electrically connected to the negative electrode of the first light-emitting element 11 located on the −X side, and one external connection terminal 110 electrically connected to the negative electrode of the second light-emitting element 21 located on the −X side. However, the electrical connection of the six external connection terminals 110 is not particularly limited. For example, the six external connection terminals 110 may include two external connection terminals 110 electrically connected to respective positive electrodes of the two first light-emitting elements 11, and two external connection terminals 110 electrically connected to respective positive electrodes of the two second light-emitting elements 21. One of the other two external connection terminals 110 may be connected to both the negative electrodes of the two first light-emitting elements 11, and the other may be connected to both the negative electrodes of the two second light-emitting elements 21.

It is noted that the number of the first light-emitting elements 11 and the number of the second light-emitting elements 21 included in one light-emitting device are not limited to the numbers indicated in FIG. 5 or 11. In addition, in one light-emitting device, the number of the first light-emitting elements 11 and the number of the second light-emitting elements 21 need not be the same, and thus the number of the first light-emitting elements 11 and the number of the second light-emitting elements 21 may be different.

In the light source according to the embodiment, during a lighting period of the light source, a continuous DC current may be used to light both of the first light-emitting element 11 and the second light-emitting element 21, instead of a pulse current. In this case, for example, the first total current value of the first light-emitting element 11 having a shorter light emission peak wavelength is larger than the second total current value of the second light-emitting element 21. As illustrated in FIG. 4, when the first light-emitting element 11 having a larger total current value is located closer to the substrate 200 in the second direction Y than the second light-emitting element 21 having a smaller total current value, in other words, when the shortest distance from the first light-emitting element 11 to the substrate 200 in the second direction Y is shorter than the shortest distance from the second light-emitting element 21 to the substrate 200 in the second direction Y, the temperature rise of the first light-emitting element 11 having a larger total current value can be reduced.

Embodiments of the present disclosure have been described above with reference to specific examples. However, the present disclosure is not limited to these specific examples. All aspects that can be practiced by a person skilled in the art modifying the design as appropriate based on the above-described embodiments of the present disclosure are also included in the scope of the present disclosure, as long as they encompass the spirit of the present disclosure. In addition, in the scope of the concepts of the present disclosure, a person skilled in the art can conceive a range of variations and modified examples, and those variations and modified examples will also fall within the scope of the present disclosure.

What is claimed is:

1. A light source comprising:
a substrate;
a first light-emitting unit disposed on the substrate and comprising one first light-emitting element or a plurality of first light-emitting elements connected in series;
a second light-emitting unit disposed on the substrate and comprising a plurality of second light-emitting elements connected in series, the number of the plurality of second light-emitting elements being greater than the number of the one or plurality of first light-emitting elements;
a power supply configured to supply electric power to the one or plurality of first light-emitting elements and the plurality of second light-emitting elements; and
one or more drivers configured to cause the one or plurality of first light-emitting elements and the plurality of second light-emitting elements to emit light of predetermined brightnesses, wherein
the first light-emitting unit and the second light-emitting unit are connected in parallel to each other with respect to the power supply,
a first light emission peak wavelength of each of the one or plurality of first light-emitting elements is different from a second light emission peak wavelength of each of the plurality of second light-emitting elements,
a second forward voltage of each of the plurality of second light-emitting elements is lower than a first forward voltage of each of the one or plurality of first light-emitting elements, and
an absolute value of a difference between a first voltage, which is a forward voltage of the first light-emitting unit, and a second voltage, which is a forward voltage of the second light-emitting unit, is lower than the second forward voltage of each of the second light-emitting elements.

2. The light source according to claim 1, wherein
the first voltage is lower than the second voltage, and
the one or more drivers are configured to control a first duty cycle for the one or plurality of first light-emitting elements and a second duty cycle for the plurality of second light-emitting elements, such that the first duty cycle is lower than the second duty cycle.

3. The light source according to claim 2, wherein a total current value of the one or plurality of first light-emitting elements is smaller than a total current value of the plurality of second light-emitting elements.

4. The light source according to claim 2, wherein the second duty cycle is equal to or less than 20 times the first duty cycle.

5. The light source according to claim 2, wherein
the first light-emitting unit comprises the plurality of first light-emitting elements,
the first light-emitting unit and the second light-emitting unit are configured with a plurality of light-emitting devices arranged in a first direction on the substrate, each of the plurality of light-emitting devices comprising one of the plurality of first light-emitting elements and one of the plurality of second light-emitting elements, and
in each of the plurality of light-emitting devices, the one of the first light-emitting elements and the one of the second light-emitting elements are arranged in a second direction orthogonal to the first direction.

6. The light source according to claim 5, wherein in each of the plurality of light-emitting devices, a shortest distance from the one of the second light-emitting elements to the substrate in the second direction is shorter than a shortest distance from the one of the first light-emitting elements to the substrate in the second direction.

7. The light source according to claim 5, wherein
a plurality of the second light-emitting units comprise a first one of the second light-emitting units and a second one of the second light-emitting units, the first one of the second light-emitting units and the second one of the second light-emitting units being connected in parallel to each other with respect to the power supply, and
in the first direction, one of the second light-emitting elements included in the second one of the second light-emitting units is located between two of the second light-emitting elements included in the first one of the second light-emitting units.

8. The light source according to claim 2, wherein
the first light-emitting unit comprises the plurality of first light-emitting elements,
the first light-emitting unit and the second light-emitting unit are configured with a plurality of light-emitting devices arranged in a first direction on the substrate, each of the plurality of light-emitting devices comprising a first predetermined number of the plurality of first light-emitting elements and a second predetermined number of the plurality of second light-emitting elements, the first predetermined number and the second predetermined number being a same number equal to or greater than two, and
in each of the plurality of light-emitting devices, the first predetermined number of the first light-emitting elements and the second predetermined number of the second light-emitting elements are arranged in a second direction orthogonal to the first direction.

9. The light source according to claim 1, wherein
the second voltage is lower than the first voltage, and
the one or more drivers are configured to control at least one of a first duty cycle for the one or plurality of first light-emitting elements and a second duty cycle for the plurality of second light-emitting elements, such that the second duty cycle is lower than the first duty cycle.

10. The light source according to claim 9, wherein a total current value of the plurality of second light-emitting elements is smaller than a total current value of the one or plurality of first light-emitting elements.

11. The light source according to claim 9, wherein the first duty cycle is equal to or less than 20 times the second duty cycle.

12. The light source according to claim 9, wherein
the first light-emitting unit comprises the plurality of first light-emitting elements,
the first light-emitting unit and the second light-emitting unit are configured with a plurality of light-emitting devices arranged in a first direction on the substrate, each of the plurality of light-emitting devices comprising one of the first light-emitting elements and one of the second light-emitting elements, and
in each of the plurality of light-emitting devices, the one of the first light-emitting elements and the one of the second light-emitting elements are arranged in a second direction orthogonal to the first direction.

13. The light source according to claim 12, wherein, in each of the plurality of light-emitting devices, a shortest distance from the one of the first light-emitting elements to the substrate in the second direction is shorter than a shortest distance from the one of the second light-emitting elements to the substrate in the second direction.

14. The light source according to claim 12, wherein
a plurality of the second light-emitting units comprise a first one of the second light-emitting units and a second one of the second light-emitting units, the first one of the second light-emitting units and the second one of the second light-emitting units being connected in parallel to each other with respect to the power supply, and
in the first direction, one of the second light-emitting elements included in the second one of the second light-emitting units is located between two of the second light-emitting elements included in the first one of the second light-emitting units.

15. The light source according to claim 8, wherein
the first light-emitting unit comprises the plurality of first light-emitting elements,
the first light-emitting unit and the second light-emitting unit are configured with a plurality of light-emitting devices arranged in a first direction on the substrate, each of the plurality of light-emitting devices comprising a first predetermined number of the plurality of first light-emitting elements and a second predetermined number of the plurality of second light-emitting elements, the first predetermined number and the second predetermined number being a same number equal to or greater than two, and
in each of the plurality of light-emitting devices, the first predetermined number of the first light-emitting elements and the second predetermined number of the second light-emitting elements are arranged in a second direction orthogonal to the first direction.

16. The light source according to claim 1, wherein
a plurality of the first light-emitting units are connected in parallel to each other with respect to the power supply, and
in each of the plurality of first light-emitting units, the number of the one or plurality of first light-emitting elements connected in series is larger than the number of the plurality of first light-emitting units connected in parallel.

17. The light source according to claim 1, wherein
the first light-emitting unit comprises the plurality of first light-emitting elements,
the first light-emitting unit and the second light-emitting unit are configured with a plurality of light-emitting devices arranged in a first direction on the substrate, each of the light-emitting devices comprising one of the plurality of first light-emitting elements and one of the plurality of the second light-emitting elements,
in each of the light-emitting devices, a shortest distance from the one of the first light-emitting elements to the substrate in the second direction is shorter than a shortest distance from the one of the second light-emitting elements to the substrate in the second direction, and
a total current value of the plurality of first light-emitting elements is larger than a total current value of the plurality of second light-emitting elements.
